(19) United States
(12) Patent Application Publication
(10) Pub. No.: US 2025/0253254 A1
(43) Pub. Date: Aug. 7, 2025

(54) SEMICONDUCTOR PACKAGE

(71) Applicant: Samsung Electronics Co., Ltd., Suwon-si (KR)

(72) Inventors: Daeyoung Jung, Suwon-si (KR); Jongbo Shim, Suwon-si (KR); Jangwoo Lee, Suwon-si (KR); Deokhee Han, Suwon-si (KR)

(21) Appl. No.: 18/828,217

(22) Filed: Sep. 9, 2024

(30) Foreign Application Priority Data
Feb. 7, 2024 (KR) 10-2024-0018800

(51) Int. Cl. H01L 23/538; H01L 23/00; H01L 23/31; H01L 25/18; H10B 80/00

(52) U.S. Cl. CPC H01L 23/5385; H01L 23/3107; H01L 23/5386; H01L 25/18; H01L 24/16; H01L 24/32; H01L 24/73; H01L 2224/16227; H01L 2224/32225; H01L 2224/73204; H10B 80/00

(57) ABSTRACT

A semiconductor package may include: a lower substrate including a lower interconnection layer; a first semiconductor chip and a second semiconductor chip spaced apart from each other on the lower substrate, each of which is electrically connected to the lower interconnection layer; an upper substrate disposed on the lower substrate, spaced apart from upper surfaces of the first and second semiconductor chips in a direction perpendicular to an upper surface of the lower substrate, and including an upper interconnection layer; connection structures disposed between the lower substrate and the upper substrate and electrically connecting the lower interconnection layer and the upper interconnection layer; a third semiconductor chip and a fourth semiconductor chip spaced apart from each other on the upper substrate, and electrically connected to the upper interconnection layer; and a molded portion disposed on the lower substrate and covering the first semiconductor chip and the second semiconductor chip.

### CROSS-REFERENCE TO RELATED APPLICATION(S)

This application claims benefit of priority under 35 U.S.C. § 119 to Korean Patent Application No. 10-2024-0018800, filed on Feb. 7, 2024, in the Korean Intellectual Property Office, the disclosure of which is incorporated herein by reference in its entirety.

### BACKGROUND

The present disclosure relates to a semiconductor package. More specifically, the present disclosure relates to a semiconductor package having improved integration and reliability.

With the development of the electronics industry, demands for higher functionality, higher speed, and miniaturization of electronic components are increasing. According to this trend, a system-in-package (SIP), which requires complexity and multifunctionality in terms of functionality, is being studied. In terms of structure, a package on package (POP) structure is being developed in which multiple semiconductor chips are stacked and mounted on a package substrate or other semiconductor packages are stacked on a semiconductor package. Specifically, research is being actively conducted to simultaneously secure miniaturization and reliability in such semiconductor packages.

### SUMMARY

An aspect of the present disclosure is to provide a semiconductor package having improved integration and improved heat dissipation characteristics.

However, the object of the present disclosure is not limited to the above-described objects, and may be variously extended without departing from the spirit and domain of the present disclosure.

According to an aspect of the present disclosure, a semiconductor package may include: a lower substrate including a lower interconnection layer; a first semiconductor chip and a second semiconductor chip spaced apart from each other on the lower substrate, each of which is electrically connected to the lower interconnection layer; an upper substrate disposed on the lower substrate, spaced apart from upper surfaces of the first and second semiconductor chips in a direction perpendicular to an upper surface of the lower substrate, and including an upper interconnection layer; connection structures disposed between the lower substrate and the upper substrate and electrically connecting the lower interconnection layer and the upper interconnection layer; a third semiconductor chip and a fourth semiconductor chip spaced apart from each other on the upper substrate, and electrically connected to the upper interconnection layer; and a molded portion disposed on the lower substrate and covering the first semiconductor chip and the second semiconductor chip.

According to an aspect of the present disclosure, a semiconductor package may include: a first semiconductor package including a lower substrate and first and second semiconductor chips spaced apart from each other on the lower substrate; a second semiconductor package spaced apart from the first semiconductor package in a direction perpendicular to the first semiconductor package, and including third and fourth semiconductor chips spaced apart from each other on the upper substrate; connection structures disposed between the first semiconductor package and the second semiconductor package to electrically connect the first semiconductor package and the second semiconductor package; and a molded portion covering the first and second semiconductor chips and surrounding at least a portion of side surfaces of the connection structures.

According to an aspect of the present disclosure, a semiconductor package may include: a lower substrate having an upper surface including a first region, a second region spaced apart from the first region, and a third region surrounding the first region and the second region, and including a lower interconnection layer; a first semiconductor chip disposed on the first region, and electrically connected to the lower interconnection layer; a second semiconductor chip disposed on the second region, and electrically connected to the lower interconnection layer; an upper substrate disposed on the lower substrate, spaced apart from upper surfaces of the first and second semiconductor chips in a direction perpendicular to an upper surface of the lower substrate, and including an upper interconnection layer; connection structures disposed on the third region of the lower substrate, and electrically connecting the lower interconnection layer and the upper interconnection layer; a third semiconductor chip disposed on the upper substrate, and at least partially overlapping the first semiconductor chip in the direction perpendicular thereto; a fourth semiconductor chip disposed on the upper substrate, and spaced apart from the third semiconductor chip; and a molded portion disposed between the lower substrate and the upper substrate and covering the first semiconductor chip and the second semiconductor chip.

A semiconductor package according to example embodiments of the present disclosure may include a first semiconductor package including at least one semiconductor chip and a second semiconductor package disposed on the first semiconductor package and including a plurality of semiconductor chips such as a logic chip and a memory chip, thereby providing a semiconductor package having improved integration. Additionally, the first semiconductor package and the second semiconductor package may be electrically connected through connection structures without a separate interposer substrate, thereby reducing the manufacturing costs of the semiconductor package.

However, the effect of the present disclosure is not limited to the above-described objects, and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view of a semiconductor package according to example embodiments of the present disclosure;

FIG. 2A is a cross-sectional view illustrating an example embodiment taken along line A-A′ of FIG. 1;

FIG. 2B is a cross-sectional view illustrating another example embodiment taken along line A-A′ of FIG. 1;

FIG. 3 is a cross-sectional view illustrating an example embodiment taken along line B-B′ of FIG. 1; and

FIGS. 4 to 11 are views illustrating an example embodiment of a method of manufacturing the semiconductor package of FIG. 1.

### DETAILED DESCRIPTION

Hereinafter, example embodiments of the present disclosure will be described in more detail with reference to the accompanying drawings. The same reference numerals are used for the same components in the drawings, and overlapping descriptions for the same components are omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper” and the like, may be used herein for ease of description to describe positional relationships, such as illustrated in the figures, e.g. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

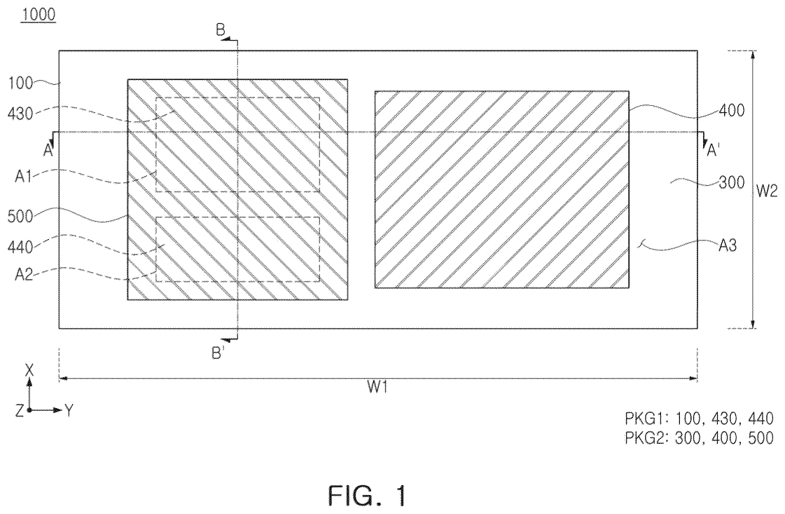

FIG. 1 is a plan view of a semiconductor package according to example embodiments of the present disclosure.

Referring to FIG. 1, a semiconductor package 1000 may include a first semiconductor package PKG1 and a second semiconductor package PKG2. In one example, the second semiconductor package PKG2 may be disposed on the first semiconductor package PKG1 (e.g., in the third direction (Z-direction)).

In one example, the first semiconductor package PKG1 may include a lower substrate 100, a first semiconductor chip 430, and a second semiconductor chip 440.

In an example embodiment, the lower substrate 100 is a support substrate on which the first semiconductor chip 430 and the second semiconductor chip 440 are mounted, and may be a substrate for a semiconductor package including a printed circuit board (PCB), a ceramic substrate, a glass substrate, and a tape interconnection substrate. In one example, the lower substrate 100 may include different materials depending on the type of substrate. For example, when the lower substrate 100 is a printed circuit board, the lower substrate 100 may be in a form in which an interconnection layer is additionally stacked on one surface or both surfaces of a copper clad laminate. In one example, a solder resist layer may be disposed on a lower surface and an upper surface of the lower substrate 100.

In an example embodiment, the lower substrate 100 may include a first region A1, a second region A2 spaced apart from the first region A1 in a first direction (X-direction), and a third region A3 surrounding the first region A1 and the second region A2. In one example, the first region A1 may be a region in which the first semiconductor chip 430 is disposed. The second region A2 may be a region in which the second semiconductor chip 440 is disposed. The third region A3 may be a region in which connection structures 180 described above are disposed.

In an example embodiment, the first semiconductor chip 430 may be disposed on one side of the lower substrate 100. The second semiconductor chip 440 may be spaced apart from the first semiconductor chip 430 in the first direction (X-direction). In one example, when viewed in plan view, an area of the second semiconductor chip 440 may be smaller than an area of the first semiconductor chip 430. However, the present disclosure is not limited thereto. An area of the second semiconductor chip 440 may be larger than an area of the first semiconductor chip 430.

In an example embodiment, the first semiconductor chip 430 may include a communication processor (CP). However, the present disclosure is not limited thereto, and the first semiconductor chip 430 may include a logic chip such as a modem, a central processing unit (CPU), or a graphic processing unit (GPU). In this document, the first semiconductor chip 430 may be referred to as a first logic chip.

In an example embodiment, the second semiconductor chip 440 may include a volatile memory chip, such as a Dynamic Random Access Memory (DRAM) or a Static Random Access Memory (SRAM), or a non-volatile memory chip, such as a Phase-change Random Access Memory (PRAM), a Magnetoresistive Random Access Memory (MRAM), a Ferroelectric Random Access Memory (FeRAM) or a Resistive Random Access Memory (RRAM). In this document, the second semiconductor chip 440 may be referred to as a first memory chip. In one example, the second semiconductor chip 440 may be electrically connected to the first semiconductor chip 430.

In an example embodiment, the second semiconductor package PKG2 may include an upper substrate 300, a third semiconductor chip 500, and a fourth semiconductor chip 400.

In an example embodiment, the upper substrate 300 is a support substrate on which the third semiconductor chip 500 and the fourth semiconductor chip 400 are mounted, and may be a substrate for a semiconductor package including a printed circuit board (PCB), a ceramic substrate, a glass substrate, and a tape interconnection substrate. In one example, the upper substrate 300 may include features identical to or substantially the same as the lower substrate 100.

In an example embodiment, the upper substrate 300 may be disposed on the lower substrate 100 to overlap the lower substrate 100 in the third direction (Z-direction). The upper substrate 300 may overlap the first and second semiconductor chips 430 and 440 disposed on the lower substrate 100 in the third direction (Z-direction).

In an example embodiment, an area of the upper substrate 300 may be the same as an area of the lower substrate 100 when viewed in plan view. However, the present disclosure is not limited thereto, and the lower substrate 100 and the upper substrate 300 may have different areas when viewed in plan view. In one example, each of the lower substrate 100 and the upper substrate 300 may have a second width W2 in the first direction (X-direction) and a first width W1 in a second direction (Y-direction). The first width W1 may be larger than the second width W2.

In an example embodiment, the third semiconductor chip 500 may be disposed on the upper substrate 300. In one example, the third semiconductor chip 500 may overlap the first region A1 and the second region A2 of the lower substrate 100 in the third direction (Z-direction). The third semiconductor chip 500 may overlap the first semiconductor chip 430 and the second semiconductor chip 440 in the third direction (Z-direction). However, the present disclosure is not limited thereto, and when viewed in plan view, depending on the area of the third semiconductor chip 500, the third semiconductor chip 500 may overlap a portion of the first semiconductor chip 430 and may not overlap the second semiconductor chip 440.

In an example embodiment, the third semiconductor chip 500 may include a volatile memory chip, such as a Dynamic Random Access Memory (DRAM) or a Static Random Access Memory (SRAM), or a non-volatile memory chip, such as a Phase-change Random Access Memory (PRAM), a Magnetoresistive Random Access Memory (MRAM), a Ferroelectric Random Access Memory (FeRAM), or a Resistive Random Access Memory (RRAM). In this document, the third semiconductor chip 500 may be referred to as a second memory chip.

In an example embodiment, the fourth semiconductor chip 400 may be disposed on the upper substrate 300, and may be spaced apart from the third semiconductor chip 500 in the second direction (Y-direction). In one example, the fourth semiconductor chip 400 may overlap a portion of the third region A3 of the lower substrate 100. The fourth semiconductor chip 400 may not overlap the first and second semiconductor chips 430 and 440 in the third direction (Z-direction).

In an example embodiment, the fourth semiconductor chip 400 may include a controller chip. In one example, the fourth semiconductor chip 400 may include a system on chip (SoC), an application processor (AP), a mobile AP, a chip set, or a set of chips. In one example, the fourth semiconductor chip 400 may be a logic chip that is different from the first semiconductor chip 430. The fourth semiconductor chip 400 may be a logic chip performing a different function from the first semiconductor chip 430. In this document, the fourth semiconductor chip 400 may be referred to as a second logic chip.

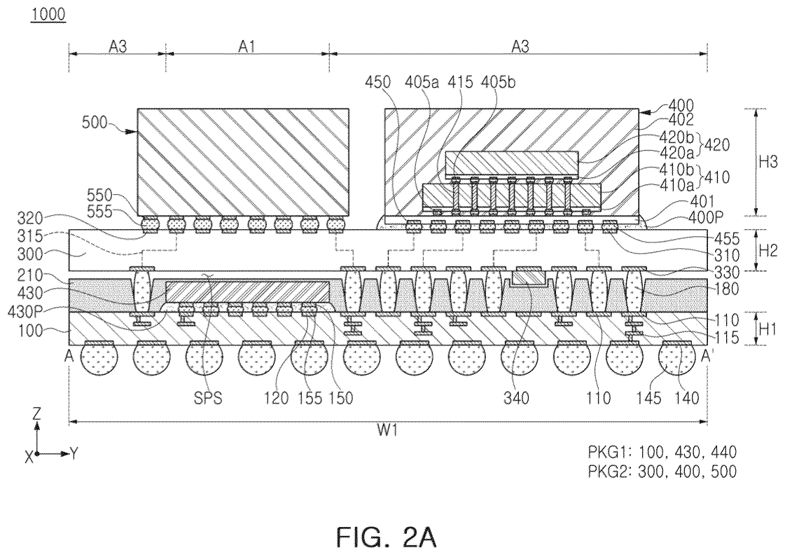

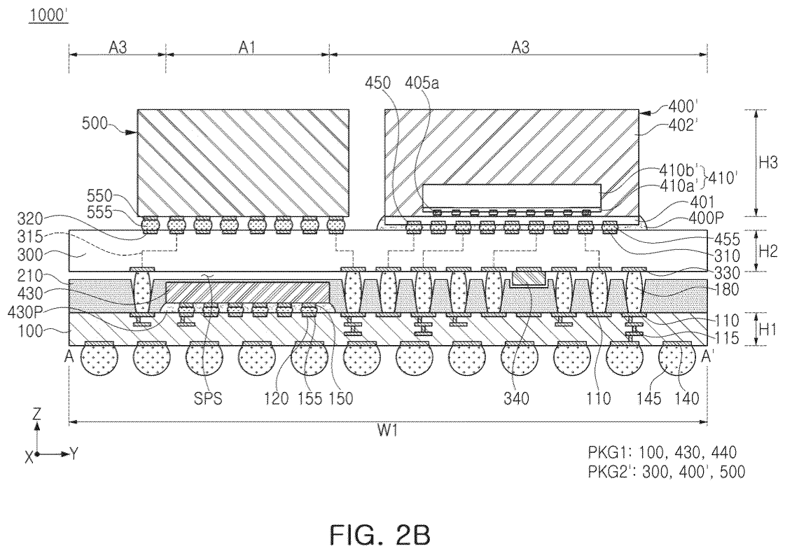

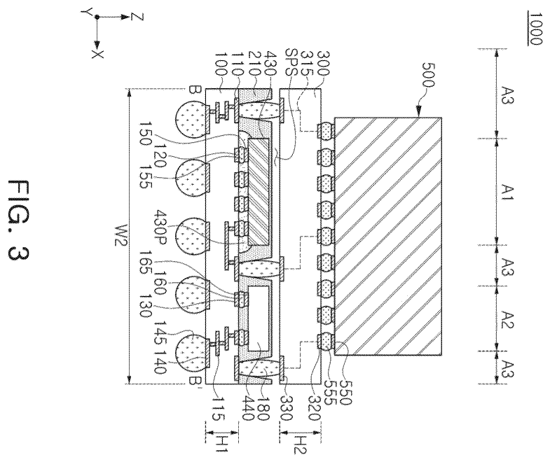

FIG. 2A is a cross-sectional view illustrating an example embodiment taken along line A-A′ of FIG. 1, and FIG. 3 is a cross-sectional view illustrating an example embodiment taken along line B-B′ of FIG. 1.

Referring to FIGS. 2A and 3, the semiconductor package 1000 may include a first semiconductor package PKG1, a second semiconductor package PKG2, connection structures 180, and a molded portion 210.

In an example embodiment, the first semiconductor package PKG1 may include a lower substrate 100 and first and second semiconductor chips 430 and 440. In one example, the first semiconductor package PKG1 may further include first upper pads 110, 120, and 130, a first lower pad 140, and a lower connection bump 145.

In an example embodiment, the lower substrate 100 may include an upper surface on which the first and second semiconductor chips 430 and 440 and the first upper pads 110, 120, and 130 are disposed, and a lower surface on which the first lower pads 140 are disposed. In example embodiments, upper surfaces of the first upper pads 110, 120, and 130 may be coplanar with an upper surface of the substrate 100, and lower surfaces of the first lower pads 140 may be coplanar with a lower surface of the substrate 100.

In an example embodiment, an upper surface of the lower substrate 100 may include a first region A1, a second region A2, and a third region A3 surrounding the first region A1 and the second region A2.

In an example embodiment, the first upper pads 110, 120, and 130 may include 1-1 upper pads 120 disposed on the first region A1 of the lower substrate 100, 1-2 upper pads 130 disposed on the second region A2, and 1-3 upper pads 110 disposed on the third region A3. In one example, the first lower pads 140 may be disposed on a lower surface of the lower substrate 100.

In an example embodiment, the first upper pads 110, 120, and 130, the first lower pad 140, and a lower interconnection layer 115 may form an electrical path connecting the upper surface and the lower surface of the lower substrate 100. In one example, the first upper pads 110, 120, and 130, the first lower pad 140, and the lower interconnection layer 115 may include a metallic material. The metallic material may include at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), and an alloy including two or more metals thereof.

In an example embodiment, the lower connection bumps 145 may be disposed on the lower surface of the lower substrate 100, and may be electrically connected to the first lower pads 140. For example, the lower connection bumps 145 may contact the first lower pads 140. In one example, the lower connection bump 145 may include tin (Sn) or an alloy including tin (Sn) (e.g., Sn—Ag—Cu).

In an example embodiment, the lower interconnection layer 115 may be buried and disposed inside the lower substrate 100. In one example, the lower interconnection layer 115 may be disposed inside the lower substrate 100 and may include multiple interconnection layers and vias connecting the multiple interconnection layers. The lower interconnection layer 115 may electrically connect the first upper pads 110, 120, and 130 and the first lower pad 140.

In an example embodiment, the first semiconductor package PKG1 may further include first connection patterns 150 and 155 and second connection patterns 160 and 165.

In an example embodiment, the first semiconductor chip 430 may be disposed on the first region A1 of the lower substrate 100 and may be electrically connected to the lower interconnection layer 115 through the first connection patterns 150 and 155 and the 1-1 upper pad 120.

In an example embodiment, the first connection patterns 150 and 155 may be disposed between the first semiconductor chip 430 and the 1-1 upper pad 120. The first connection patterns 150 and 155 may include a first connection pad 150 disposed below the first semiconductor chip 430, and a first connection bump 155 disposed between the first connection pad 150 and the 1-1 upper pad 120. The first connection bumps 155 may contact lower surfaces of the first connection pads 150 and upper surfaces of the 1-1 upper pads 120.

In an example embodiment, the first semiconductor package PKG1 may further include a first underfill 430P disposed between the first semiconductor chip 430 and the lower substrate 100. In one example, the first underfill 430P may fill a space between the first region A1 of the lower substrate 100 and a lower surface of the first semiconductor chip 430. The first underfill 430P may contact an upper surface of the lower substrate 100 and the lower surface of the first semiconductor chip 430. The first underfill 430P may be disposed and/or formed by a capillary underfill (CUF) process, but the present disclosure is not limited thereto. The first underfill 430P may include an insulating resin. For example, the first underfill 430P may include a thermosetting resin, a thermoplastic resin such as polyimide, or an inorganic filler or/and a prepreg including glass fiber, ABF, FR-4, BT, and EMC.

In an example embodiment, the second semiconductor chip 440 may be spaced apart from the first semiconductor chip 430 in the first direction (X-direction). In one example, the second semiconductor chip 440 may be disposed on the second region A2 of the lower substrate 100 and may be electrically connected to the lower interconnection layer 115 through the second connection patterns 160 and 165 and the 1-2 upper pads 130. In one example, the second semiconductor chip 440 may be electrically connected to the first semiconductor chip 430 through the 1-2 upper pads 130 and the lower interconnection layer 115. In one example, the second semiconductor chip 440 may be a first memory chip for the first semiconductor chip 430, which is a first logic chip, and may be disposed on the same level as the first semiconductor chip 430.

In an example embodiment, the second connection patterns 160 and 165 may be disposed between the second semiconductor chip 440 and the 1-2 upper pads 130. The second connection patterns 160 and 165 may include a second connection pad 165 disposed below the second semiconductor chip 440, and a second connection bump 160 disposed between the second connection pad 165 and the 1-2 upper pads 130. The second connection bumps 160 may contact lower surfaces of the second connection pads 165 and upper surfaces of the 1-2 upper pads 130.

In an example embodiment, a height of the first semiconductor chip 430 in the vertical direction (Z-direction) may be greater than a height of the second semiconductor chip 440 in the vertical direction (Z-direction). For example, the height of the first semiconductor chip 430 in the vertical direction (Z-direction) may be about 85 μm, and the height of the second semiconductor chip 440 in the vertical direction (Z-direction) may be about 65 μm. Here, the “height” of the first semiconductor chip 430 in the vertical direction (Z-direction) may refer to the distance between the lower and upper surfaces of the first semiconductor chip 430, and the “height” of the second semiconductor chip 440 in the vertical direction (Z-direction) may refer to the distance between the lower and upper surfaces of the second semiconductor chip 440. However, the present disclosure is not limited thereto, and the height of the second semiconductor chip 440 in the vertical direction may be equal to or greater than the height of the first semiconductor chip 430 in the vertical direction.

In an example embodiment, the second semiconductor package PKG2 may include an upper substrate 300 and third and fourth semiconductor chips 500 and 400. In one example, the second semiconductor package PKG2 may further include second upper pads 310 and 320, a second lower pad 330, and a passive element 340.

In an example embodiment, the upper substrate 300 may include an upper surface on which the third semiconductor chip 500, the fourth semiconductor chip 400 and the second upper pads 310 and 320 are disposed, and a lower surface facing the upper surface of the lower substrate 100 and on which the second lower pads 330 and the passive element 340 are disposed. Upper surfaces of the second upper pads 310 and 320 may be coplanar with an upper surface of the upper substrate 300, and lower surfaces of the second lower pads 330 may be coplanar with a lower surface of the upper substrate 300.

In an example embodiment, the upper substrate 300 may completely overlap the lower substrate 100 in the vertical direction (e.g., the third direction (Z-direction)). In one example, the upper substrate 300 may overlap the first region A1, the second region A2, and the third region A3 of the upper surface of the lower substrate 100 in the third direction (Z-direction). In one example, the upper substrate 300 may be spaced apart from the first semiconductor chip 430 and the second semiconductor chip 440 disposed on the lower substrate 100 in the vertical direction (Z-direction).

In an example embodiment, a second height H2 of the upper substrate 300 in the vertical direction (Z-direction) may be greater than a first height H1 of the lower substrate 100 in the vertical direction (Z-direction). In one example, the first height H1 may be about 140 μm to 160 μm. The second height H2 may be about 200 μm to 320 μm. The first height H1 may be a distance between the lower and upper surfaces of the lower substrate 100, and the second height H2 may be a distance between the lower and upper surfaces of the upper substrate 300. In one example, the upper substrate 300 may include more interconnection layers than the lower substrate 100. For example, the upper substrate 300 includes six interconnection layers, and the lower substrate 100 may include four interconnection layers.

In an example embodiment, the second upper pads 310 and 320 may include a 2-1 upper pad 320 disposed on an upper surface of the upper substrate 300 and a 2-2 upper pad 310 disposed on the upper surface of the upper substrate 300 and spaced apart from the 2-1 upper pad 320 in the second direction (Y-direction).

In an example embodiment, the second lower pad 330 may be disposed on a lower surface of the upper substrate 300. The second lower pad 330 may be disposed on the lower surface of the upper substrate 300 to overlap the third region A3 of the lower substrate 100 in the vertical direction (Z-direction). The second lower pad 330 may overlap the 1-3 upper pad 110 in the vertical direction (Z-direction).

In an example embodiment, the passive element 340 may be disposed on the lower surface of the upper substrate 300. For example, the passive element 340 may contact the lower surface of the upper substrate 300. The passive element 340 may contact the lower surface of the second lower pad 330. The passive element 340 may be electrically connected to an upper interconnection layer 315 through a bonding pad disposed on the lower surface of the upper substrate 300. For example, the passive element 340 may contact the lower surface of the second lower pad 330. The passive element 340 may be disposed on the lower surface of the upper substrate 300, thus shortening a connection path between the third semiconductor chip 500 and/or the fourth semiconductor chip 400. In one example, the passive element 340 may include, for example, a capacitor, an inductor, or beads. The passive element 340 may improve signal integrity (SI) and/or power integrity (PI) characteristics of the semiconductor package. In one example, the passive element 340 may overlap the third region A3 of the lower substrate 100 in the vertical direction (Z-direction). The passive element 340 may overlap the fourth semiconductor chip 400 in the vertical direction (Z-direction). Although one passive element 340 is illustrated, embodiments may include two or more passive elements 340.

In an example embodiment, the upper interconnection layer 315 may be buried and disposed inside the upper substrate 300. In one example, the upper interconnection layer 315 may be disposed inside the upper substrate 300 and may include multiple interconnection layers and vias connecting the multiple interconnection layers. The upper interconnection layer 315 may electrically connect the second upper pads 310 and 320 and the second lower pads 330.

In an example embodiment, the second semiconductor package PKG2 may further include third connection patterns 550 and 555 and fourth connection patterns 450 and 455.

In an example embodiment, the third semiconductor chip 500 may be disposed on the upper surface of the upper substrate 300 and may be electrically connected to the upper interconnection layer 315 through the third connection patterns 550 and 555 and the 2-1 upper pad 320. In one example, the third semiconductor chip 500 may overlap at least a portion of the first semiconductor chip 430 and the second semiconductor chip 440 in the vertical direction (Z-direction).

In an example embodiment, the third connection patterns 550 and 555 may be disposed between the third semiconductor chip 500 and the 2-1 upper pads 320. The third connection patterns 550 and 555 may include a third connection pad 550 disposed below the third semiconductor chip 500 and a third connection bump 555 disposed between the third connection pad 550 and the 2-1 upper pad 320. For example, the third connection bumps 555 may contact lower surfaces of the third connection pads and upper surfaces of the 2-1 upper pads 320.

In an example embodiment, the fourth semiconductor chip 400 may be spaced apart from the third semiconductor chip 500 in the second direction (Y-direction) and may be disposed on the upper substrate 300. The fourth semiconductor chip 400 may be electrically connected to the upper interconnection layer 315 through the fourth connection patterns 450 and 455 and the 2-2 upper pads 310. In one example, the fourth semiconductor chip 400 may overlap connection structures 180 described below in the vertical direction (Z-direction). In one example, the fourth semiconductor chip 400 may not overlap the first semiconductor chip 430 and the second semiconductor chip 440.

In an example embodiment, the fourth connection patterns 450 and 455 may be disposed between the fourth semiconductor chip 400 and the 2-2 upper pads 310. The fourth connection patterns 450 and 455 may include a fourth connection pad 450 disposed below the fourth semiconductor chip 400 and a fourth connection bump 455 disposed between the fourth connection pad 450 and the 2-2 upper pad 310. The fourth connection bumps 455 may contact lower surfaces of the fourth connection pads 450 and upper surfaces of the 2-2 upper pads 310.

In an example embodiment, the fourth semiconductor chip 400 may include a substrate 401, a plurality of semiconductor dies 410 and 420, die connection patterns 405a and 405b, and an encapsulant 402.

In an example embodiment, the substrate 401 may be a substrate on which a plurality of semiconductor dies 410 and 420 are mounted. The substrate 401 may have characteristics similar to the lower substrate 100 and/or the upper substrate 300. The substrate 401 may be disposed on the 2-2 upper pads 310.

In an example embodiment, the plurality of semiconductor dies 410 and 420 may be sequentially disposed on the substrate 401 in the vertical direction (Z-direction). In one example, the plurality of semiconductor dies 410 and 420 may include a first die 410 and a second die 420. The first die 410 and the second die 420 may be sequentially disposed on the substrate 401 in the vertical direction (Z-direction). Although the number of stacked semiconductor dies is illustrated as two, the present disclosure is not limited thereto, and two or more semiconductor dies may be included.

In an example embodiment, the first die 410 may include a first base substrate 410a, a first circuit layer 410b disposed on the first base substrate 410a, and through-electrodes 415 penetrating through the first die 410 in the vertical direction (Z-direction). The first die 410 may be disposed on the substrate 401 through the first die connection pattern 405a disposed on a lower surface of the first base substrate 410a, and may be electrically connected to the substrate 401.

In an example embodiment, the second die 420 may include a second base substrate 420a and a second circuit layer 420b disposed on the second base substrate 420a. The second die 420 may be disposed on the first die 410 through the second die connection pattern 405b disposed on a lower surface of the second base substrate 420a, and may be electrically connected to the first die 410.

In an example embodiment, the first and second base substrates 410a and 420a include a semiconductor element such as silicon (Si) or germanium (Ge), or may include compound semiconductors such as silicon carbide (SiC), gallium arsenide (GaAs), indium arsenide (InAs), or indium phosphide (InP).

In an example embodiment, each of the first and second circuit layers 410b and 420b may be disposed on active surfaces of the first and second base substrates 410a and 420a, and may include an interlayer insulating layer and an interconnection structure.

In an example embodiment, the through-electrodes 415 may penetrate through the first die 410 and electrically connect the first and second die connection patterns 405a and 405b.

In an example embodiment, the encapsulant 402 may surround the substrate 401 and the plurality of semiconductor dies 410 and 420.

In an example embodiment, the second semiconductor package PKG2 may further include a second underfill 400P disposed between the fourth semiconductor chip 400 and the upper substrate 300. The second underfill 400P may fill a space between a lower surface of the fourth semiconductor chip 400 and the upper substrate 300 and a space between the fourth connection patterns 450 and 455. In one example, the second underfill 400P may cover at least a portion of a side surface of the substrate 401. The second underfill 400P may be disposed and/or formed by a capillary underfill (CUF) process, but the present disclosure not limited thereto. The second underfill 400P may include an insulating resin.

In an example embodiment, a third height H3 of the fourth semiconductor chip 400 in the vertical direction (Z-direction) may be greater than a height of the first semiconductor chip 430 in the vertical direction and a height of the second semiconductor chip 440 in the vertical direction. For example, the third height H3 may be about 500 μm to 600 μm. The third height H3 of the fourth semiconductor chip 400 may be the distance between lower and upper surfaces of the fourth semiconductor chip 400.

In an example embodiment, the semiconductor package 1000 may include connection structures 180 disposed on 1-3 upper pads 110. The connection structures 180 may contact upper surfaces of 1-3 upper pads 110. For example, each connection structure 180 may contact the upper surface of a corresponding one of the 1-3 upper pads 110. In one example, the connection structures 180 may be disposed on the third region A3 of the lower substrate 101. The connection structures 180 may be disposed between the second lower pad 330 of the upper substrate 300 and the 1-3 upper pad 110 and may electrically connect the lower interconnection layer 115 of the lower substrate 100 and the upper interconnection layer 315 of the upper substrate 300. The connection structures 180 may include a first contact portion in contact with the 1-3 upper pad 110, a second contact portion in contact with the second lower pad 330, and a side surface portion connecting the first contact portion and the second contact portion. In one example, the connection structures 180 may provide a vertical connection path electrically connecting the lower interconnection layer 115 and the upper interconnection layer 315. In one example, the connection structures 180 may include solder portions. The connection structures 180 may have a spherical or ball shape formed of low melting point metals, such as tin (Sn), indium (In), bismuth (Bi), antimony (Sb), copper (Cu), silver (Ag), zinc (Zn), and lead (Pb), and an alloy including the same (for example, Sn—Ag—Cu).

In an example embodiment, the semiconductor package 1000 may include a molded portion 210 covering the first and second semiconductor chips 430 and 440 on the upper surface of the lower substrate 100. In one example, the molded portion 210 may cover the upper surface of the lower substrate 100. In one example, the molded portion 210 may completely cover the first and second semiconductor chips 430 and 440. In one example, the molded portion 210 may cover at least a portion of side surface portions of the connection structures 180. For example, the molded portion may contact side surface portions of the connection structures 180. In one example, at least a portion of the side surface portions of the connection structures 180 extending in the vertical direction (Z-direction) may be surrounded by the molded portion 210. The side surface portions of the connection structures 180 adjacent to the first contact portion of the connection structures 180 may be surrounded by the molded portion 210, but the side surface portions of the connection structures 180 adjacent to the second contact portion of the connection structures 180 may not be surrounded by the molded portion 210. The side surface portions of the connection structures 180 that are not surrounded by the molded portion 210 may be exposed to the outside. In one example, the molded portion 210 may have a molded underfill (MUF) structure, but the present disclosure is not limited thereto. In one example, the molded portion 210 may not cover a side surface of the lower substrate 100.

In an example embodiment, the connection structures 180 may be disposed between the upper surface of the lower substrate 100 and the lower surface of the upper substrate 300 and may electrically connect the first semiconductor package PKG1 and the second semiconductor package PKG2 and may simultaneously support the second semiconductor package PKG2. In one example, the molded portion 210 may cover the first and second semiconductor chips 430 and 440, and may surround at least a portion of the side surfaces of the connection structures 180 to support the connection structures 180, thus distributing the pressure applied to the connection structures 180. In example embodiments, upper surfaces of the connection structures 180 may be at a higher level than an upper surface of the molded portion 210.

In an example embodiment, a separation space SPS may be formed between the molded portion 210 and the upper substrate 300. For example, an upper surface of the molded portion 210 may be spaced apart from the lower surface of the upper substrate 300 by the separation space SPS. In one example, the side surface portions of the connection structures 180 adjacent to the second contact portions of the connection structures 180 that are not surrounded by the molded portion 210 may be exposed through the separation space SPS.

In an example embodiment, heat generated in the first semiconductor chip 430 and/or the second semiconductor chip 440 may be discharged to the outside through the separation space SPS.

As the heat generated from the first semiconductor chip 430 and/or the second semiconductor chip 440 disposed between the lower surface of the lower substrate 100 and the upper substrate 300 may be discharged through the separation space SPS, the semiconductor package 1000 according to example embodiments of the present disclosure may have excellent heat dissipation characteristics, thereby providing a semiconductor package having increased reliability.

FIG. 2B is a cross-sectional view illustrating another example embodiment along line A-A′ in FIG. 1.

Among the components other than a fourth semiconductor chip 400′ illustrated in FIG. 2B, overlapping descriptions of components that are identical to or correspond to those illustrated in FIG. 2A will be omitted.

Referring to FIG. 2B, a semiconductor package 1000′ may include a first semiconductor package PKG1 and a second semiconductor package PKG2′, connection structures 180, and a molded portion 210.

In an example embodiment, the second semiconductor package PKG2′ may include an upper substrate 300, a third semiconductor chip 500, and a fourth semiconductor chip 400′.

In an example embodiment, the fourth semiconductor chip 400′ may include a single-layer semiconductor die. In one example, the fourth semiconductor chip 400′ may include a semiconductor die 410′ and an encapsulant 402′. In one example, semiconductor die 410′ may be disposed on the substrate 401 as one semiconductor die. The semiconductor die 410′ may include a base substrate 210a′ and a circuit layer 210b′ disposed on the base substrate 210a′. In one example, the encapsulant 402′ may surround semiconductor die 410′ on the substrate 401.

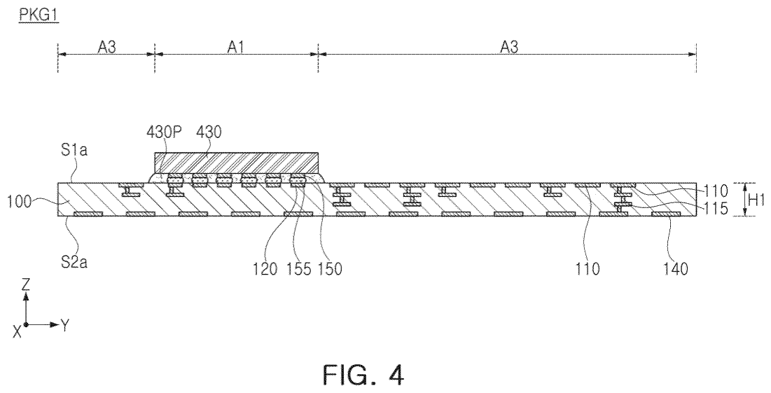

FIGS. 4 to 11 are views illustrating an example embodiment of a method of manufacturing the semiconductor package of FIG. 1.

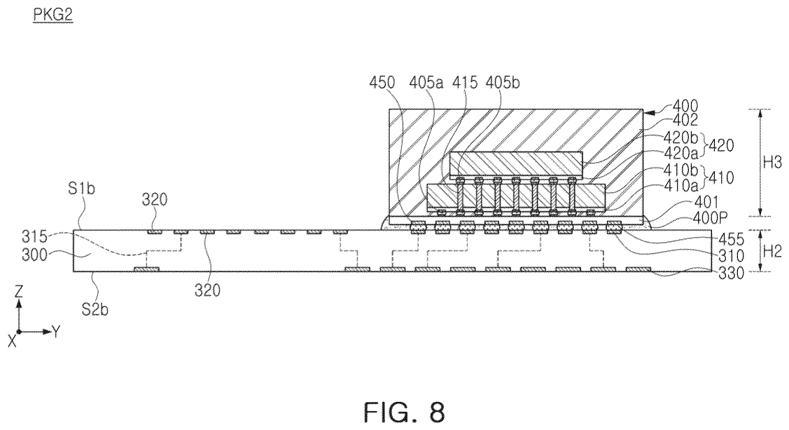

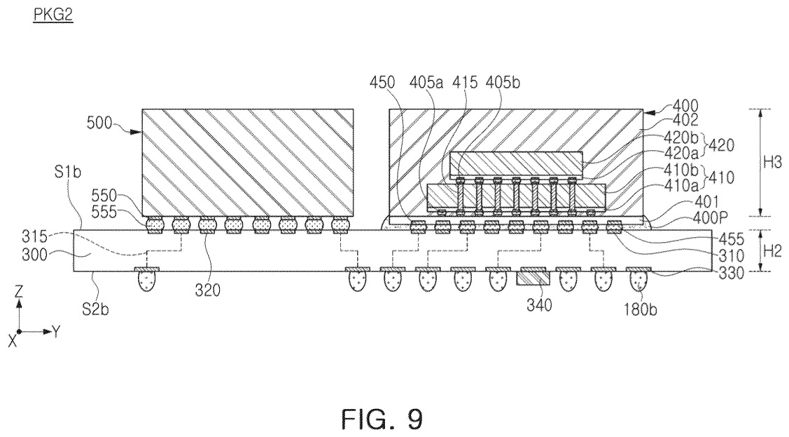

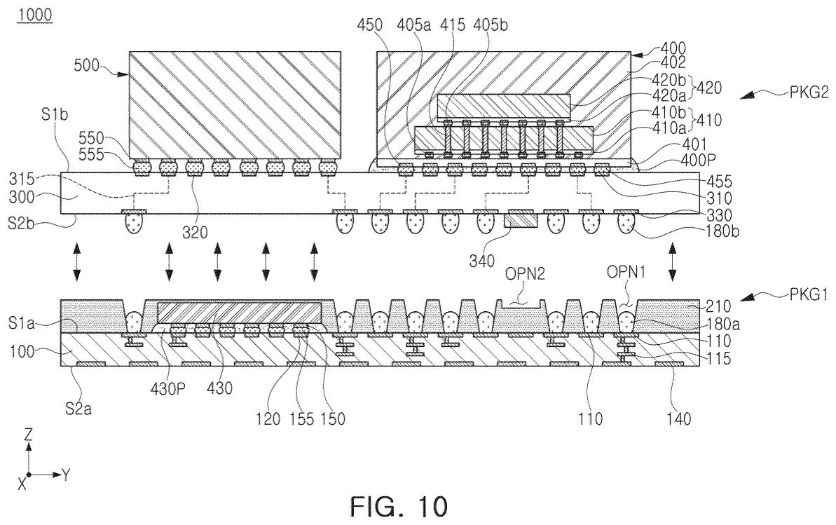

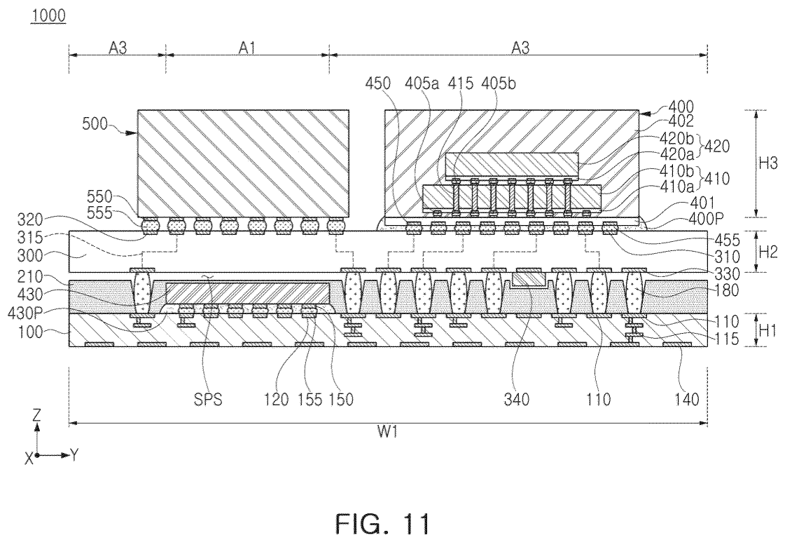

FIGS. 4 to 7 are views illustrating an example embodiment of a method of manufacturing a first semiconductor package PKG1 of a semiconductor package (e.g., the semiconductor package 1000 of FIG. 1). FIGS. 8 and 9 are views illustrating an example embodiment of a method of manufacturing the second semiconductor package PKG2 of the semiconductor package 1000. FIGS. 10 and 11 are views illustrating an example embodiment of a method of manufacturing a semiconductor package 1000 using the first semiconductor package PKG1 and the second semiconductor package PKG2.

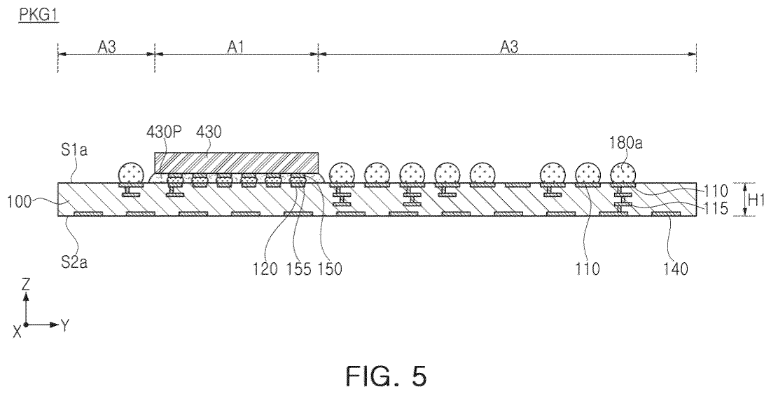

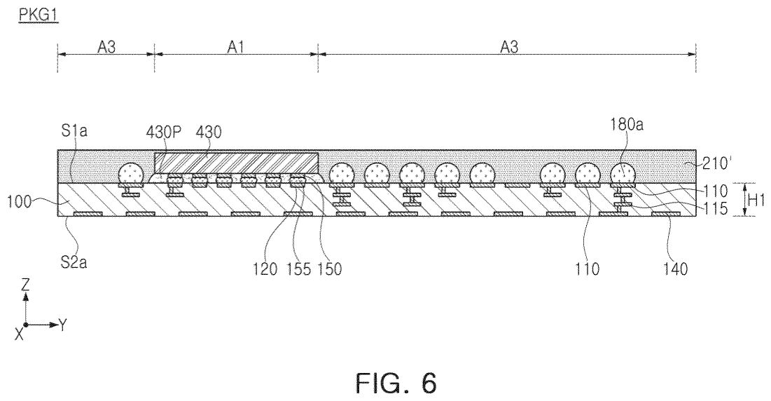

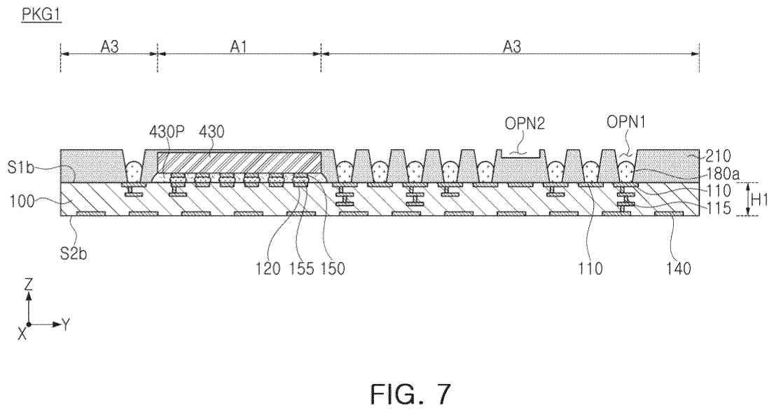

Referring to FIGS. 4 to 7, the method of manufacturing the first semiconductor package PKG1 according to example embodiments may include forming a first semiconductor chip 430 on a first region A1 of a lower substrate 100 (see FIG. 4), forming a first solder portion 180a on a third region A3 of the lower substrate 100 (see FIG. 5), forming a molded portion 210′ covering the first semiconductor chip 430 and the first solder portion 180a on the lower substrate 100 (see FIG. 6), and forming a first opening OPN1 exposing an upper portion of the first solder portion 180a′ in the molded portion 210′ (see FIG. 7).

Referring to FIGS. 8 and 9, the method of manufacturing the second semiconductor package PKG2 according to example embodiments may include forming a fourth semiconductor chip 400 on an upper surface S2a of an upper substrate 300 (see FIG. 8), forming a third semiconductor chip 500 spaced apart from the fourth semiconductor chip 400 in the second direction (Y-direction) on an upper surface S2a of the upper substrate 300, and forming a second solder portion 180b on a lower surface S2b of the upper substrate 300 (see FIG. 9).

Referring to FIGS. 10 and 11, the semiconductor package 1000 according to example embodiments may include arranging the second semiconductor package PKG2 on the first semiconductor package PKG1 so that an upper surface Sla of the lower substrate 100 of the first semiconductor package PKG1 faces the lower surface S2b of the upper substrate 300 of the second semiconductor package PKG2, and forming connection structures 180 by bonding the first solder portion 180a of the first semiconductor package PKG1 and the second solder portion 180b of the second semiconductor package PKG2.

Referring to FIGS. 4 and 5, the lower substrate 100 may include an upper surface S1a on which the first semiconductor chip 430 and the first solder portion 180a are formed, and a lower surface S1b facing the upper surface Sla. The upper surface Sla of the lower substrate 100 may include a first region A1 and a third region A3 surrounding the first region A1. 1-1 upper pads 120 may be formed on the first region A1, and 1-3 upper pads 110 may be formed on the third region A3. First lower pads 140 may be formed on the lower surface S1b of the lower substrate 100. In one example, the first semiconductor chip 430 may be formed on the 1-1 upper pads 120. The first solder portions 180a may be formed on the 1-3 upper pads 110. Each first solder portion 180a may contact a corresponding one of the 1-3 upper pads 110.

Referring to FIG. 6, a molded portion 210′ covering the upper surface Sla of the lower substrate 100 may be formed. In one example, the molded portion 210′ may be formed through a molded underfill (MUF) process. The molded portion 210′ may completely cover the first semiconductor chip 430 (and the second semiconductor chip 440 of FIG. 1) and the first solder portion 180a disposed on the upper surface Sla of the lower substrate 100.

Referring to FIG. 7, the molded portion 210′ may be etched to form first openings OPN1 exposing the first solder portions 180a. The molded portion 210′ may be etched in a laser drilling process (LDP). The first openings OPN1 may have an inclined side surface in which a width thereof becomes smaller toward the bottom. The first solder portions 180a adjacent to the upper surface Sla of the lower substrate 100 may be surrounded by the molded portion 210. An upper portion of each of the first solder portions 180a may be exposed through the first openings OPN1.

In an example embodiment, the method of manufacturing the second semiconductor package PK2 may further include forming a second opening OPN2 accommodating a passive element (e.g., the passive element 340 of FIG. 2A) by etching the molded portion 210′. In one example, in a process in which a first solder portion 180a of the first semiconductor package PKG1 and a second solder portion 180b of the second semiconductor package PKG2 to be described below come into contact with each other, the passive element 340 disposed on the lower surface S2b of the upper substrate 300 may be accommodated in the second opening OPN2.

Referring to FIGS. 8 and 9, the upper substrate 300 may include an upper surface S2a on which the third semiconductor chip 500 and the fourth semiconductor chip 400 are formed, and a lower surface S2b facing the upper surface S2a and facing the upper surface Sla of the lower substrate 100 in a subsequent process.

Referring to FIG. 10, an upper surface S1a of the lower substrate 100 of the first semiconductor package PKG1 and a lower surface S2b of the upper substrate 300 of the second semiconductor package PKG2 may be arranged to face each other. First solder portions 180a disposed on the upper surface S1a of the lower substrate 100 and second solder portions 180b disposed on the lower surface S2b of the upper substrate 300 may be overlapped in the vertical direction (Z-direction).

Referring to FIGS. 10 and 11, the first solder portions 180a disposed on the upper surface S1a of the lower substrate 100 and the second solder portions 180b disposed on the lower surface S2b of the upper substrate 300 may be bonded at a first temperature to form connection structures 180. The first temperature may include a temperature range at which the first solder portions 180a and the second solder portions 180b may be bonded. In one example, the first temperature may be about 160° C. However, the present disclosure is not limited thereto. In one example, the first semiconductor package PKG1 and the second semiconductor package PKG2 may be physically and electrically connected through the connection structures 180.

In an example embodiment, as the upper surface S1a of the lower substrate 100 and the lower surface S2b of the upper substrate 300 are adjacent to each other, the first solder portions 180a may be bonded to the second solder portions 180b. At least a portion of the second solder portions 180b may be filled in the first opening OPN1. The second solder portions 180b adjacent to the upper substrate 300 may be exposed through the separation space (SPS) between the molded portion 210 and the upper substrate 300.

In an example embodiment, after forming the connection structures 180, the semiconductor package 1000 may further include forming lower connection bumps (e.g., the lower connection bumps 145 of FIG. 2A).

In the method of manufacturing a semiconductor package according to example embodiments of the present disclosure, the second semiconductor package PKG2 including the upper substrate 300 on which the third semiconductor chip 500 and the fourth semiconductor chip 400 are mounted may be disposed on the first semiconductor package PKG1 including the lower substrate 100 on which the first semiconductor chip 430 and the second semiconductor chip 440 are mounted, and thus, since a separate interposer substrate is not required in a semiconductor package manufacturing process, the manufacturing costs of semiconductor packages may be reduced.

While example embodiments have been illustrated and described above, it will be apparent to those skilled in the art that modifications and variations could be made within a scope not departing from the spirit and region of the present disclosure as defined by the appended claims.

What is claimed is:

1. A semiconductor package, comprising:
a lower substrate including a lower interconnection layer;
a first semiconductor chip and a second semiconductor chip spaced apart from each other on the lower substrate, each of which is electrically connected to the lower interconnection layer;
an upper substrate disposed on the lower substrate, spaced apart from upper surfaces of the first and second semiconductor chips in a direction perpendicular to an upper surface of the lower substrate, and including an upper interconnection layer;
connection structures disposed between the lower substrate and the upper substrate and electrically connecting the lower interconnection layer and the upper interconnection layer;
a third semiconductor chip and a fourth semiconductor chip spaced apart from each other on the upper substrate, and electrically connected to the upper interconnection layer; and
a molded portion disposed on the lower substrate and covering the first semiconductor chip and the second semiconductor chip.

2. The semiconductor package of claim 1, wherein the molded portion completely covers the first semiconductor chip and the second semiconductor chip, and covers a portion of side surfaces of the connection structures.

3. The semiconductor package of claim 1, wherein side surfaces of the connection structures adjacent to the upper substrate are exposed through a separation space between the molded portion and the upper substrate.

4. The semiconductor package of claim 1, wherein a height of the upper substrate in the direction perpendicular thereto is greater than a height of the lower substrate in the direction perpendicular thereto.

5. The semiconductor package of claim 1, wherein the connection structures surround the first semiconductor chip and the second semiconductor chip.

6. The semiconductor package of claim 1, wherein the fourth semiconductor chip does not overlap the first semiconductor chip and the second semiconductor chip in the direction perpendicular thereto.

7. The semiconductor package of claim 1, wherein a height of the first semiconductor chip in the direction perpendicular thereto is different from a height of the second semiconductor chip in the direction perpendicular thereto.

8. The semiconductor package of claim 1,
wherein the connection structures include a first contact portion in contact with the lower substrate, a second contact portion in contact with the upper substrate, and a side surface portion connecting the first contact portion and the second contact portion, and
wherein the molded portion covers a portion of the side surface portion of the connection structures, and a remaining portion of the side surface portion is exposed by a first opening of the molded portion.

9. The semiconductor package of claim 1, further comprising:
a passive element disposed on a lower surface of the lower substrate,
wherein the molded portion includes a second opening accommodating at least a portion of the passive element.

10. The semiconductor package of claim 9, wherein the passive element is surrounded by the connection structures and overlaps the fourth semiconductor chip in the direction perpendicular thereto.

11. The semiconductor package of claim 1,
wherein the first semiconductor chip includes a communication processor (CP) chip,
wherein the second semiconductor chip includes a first memory chip electrically connected to the first semiconductor chip,
wherein the third semiconductor chip includes a second memory chip, and
wherein the fourth semiconductor chip includes an application processor (AP) chip.

12. The semiconductor package of claim 11, wherein a height of the fourth semiconductor chip in the direction perpendicular thereto is greater than a height of the first semiconductor chip in the direction perpendicular thereto and a height of the second semiconductor chip in the direction perpendicular thereto.

13. The semiconductor package of claim 1, wherein the molded portion does not cover a side surface of the lower substrate.

14. A semiconductor package, comprising:
a first semiconductor package including a lower substrate and first and second semiconductor chips spaced apart from each other on the lower substrate;
a second semiconductor package spaced apart from the first semiconductor package in a direction perpendicular to the first semiconductor package, and including third and fourth semiconductor chips spaced apart from each other on an upper substrate;
connection structures disposed between the first semiconductor package and the second semiconductor package to electrically connect the first semiconductor package and the second semiconductor package; and
a molded portion covering the first and second semiconductor chips and surrounding at least a portion of side surfaces of the connection structures.

15. The semiconductor package of claim 14, wherein the connection structures are disposed between the lower substrate and the upper substrate and surround the first and second semiconductor chips.

16. The semiconductor package of claim 14,
wherein a height of the upper substrate in the direction perpendicular thereto is greater than a height of the lower substrate in the direction perpendicular thereto, and
wherein when viewed in plan view, an area of the lower substrate is equal to an area of the upper substrate.

17. The semiconductor package of claim 14, wherein a lower surface of the upper substrate is spaced apart from the molded portion in the direction perpendicular thereto.

18. A semiconductor package, comprising:
a lower substrate having an upper surface including a first region, a second region spaced apart from the first region, and a third region surrounding the first region and the second region, and including a lower interconnection layer;
a first semiconductor chip disposed on the first region, and electrically connected to the lower interconnection layer;
a second semiconductor chip disposed on the second region, and electrically connected to the lower interconnection layer;
an upper substrate disposed on the lower substrate, spaced apart from upper surfaces of the first and second semiconductor chips in a direction perpendicular to an upper surface of the lower substrate, and including an upper interconnection layer;
connection structures disposed on the third region of the lower substrate, and electrically connecting the lower interconnection layer and the upper interconnection layer;
a third semiconductor chip disposed on the upper substrate, and at least partially overlapping the first semiconductor chip in the direction perpendicular thereto;
a fourth semiconductor chip disposed on the upper substrate, and spaced apart from the third semiconductor chip; and
a molded portion disposed between the lower substrate and the upper substrate and covering the first semiconductor chip and the second semiconductor chip.

19. The semiconductor package of claim 18, wherein the fourth semiconductor chip overlaps the connection structures in the direction perpendicular thereto.

20. The semiconductor package of claim 18, wherein the connection structures include solder portions in contact with the upper surface of the lower substrate and a lower surface of the upper substrate.
